(19) United States
(12) Patent Application Publication
(10) Pub. No.: US 2020/0194595 A1
(43) Pub. Date: Jun. 18, 2020

(54) FLEXIBLE THIN-FILM TRANSISTOR USING TWO-DIMENSIONAL SEMICONDUCTOR MATERIAL

(71) Applicant: Korea Advanced Institute of Science and Technology, Daejeon (KR)

(72) Inventors: Sung-Yool CHOI, Daejeon (KR); Young jun WOO, Daejeon (KR)

(73) Assignee: Korea Advanced Institute of Science and Technology, Daejeon (KR)

(21) Appl. No.: 16/715,021

(22) Filed: Dec. 16, 2019

(30) Foreign Application Priority Data
Dec. 14, 2018 (KR) 10-2018-0162133

(51) Int. Cl. H01L 29/786; H01L 29/66; H01L 21/02

(52) U.S. Cl. CPC H01L 29/78681; H01L 21/0228; H01L 29/66742; H01L 29/78603

(57) ABSTRACT

Provided is a flexible thin-film transistor using a two-dimensional semiconductor material, which includes: a flexible substrate; a channel formed on the flexible substrate and formed of a two-dimensional semiconductor material; a gate insulator and a gate electrode stacked sequentially on the channel; and source and drain electrodes formed on the channel as being spaced apart from the gate electrode.

### CROSS-REFERENCE TO RELATED APPLICATION

This application claims the benefit under 35 USC § 119(a) of Korean Patent Application No. 10-2018-0162133 filed on Dec. 14, 2018, in the Korean Intellectual Property Office, the entire disclosure of which is incorporated herein by reference for all purposes.

### TECHNICAL FIELD

The present disclosure relates to a flexible thin-film transistor using a two-dimensional semiconductor material, more particularly to a flexible thin-film transistor array that can be used as a display driving circuit, which is fabricated on a flexible substrate through chemical vapor deposition and exhibits flexibility and transistor driving characteristics at the same time.

### BACKGROUND ART

A two-dimensional semiconductor material has drawn a lot of attentions due to superior electrical, mechanical and optical properties. In general, the two-dimensional semiconductor material refers to a layered semiconductor material which has a strong covalent bond in the horizontal direction and a weak van der Waals bond in the vertical direction. Although various methods of utilizing two-dimensional semiconductor materials, e.g., transition metal dichalcogenide compounds, as devices are presented, application as effective devices has not been disclosed yet.

For example, Korean Patent Publication No. 10-2017-0098053 discloses a thin-film transistor wherein a transition metal dichalcogenide compound is used on a substrate as a channel material. Although it is advantageous in terms of flexibility and miniaturization when compared with display driving thin-film transistors based on amorphous silicon, low-temperature polycrystalline silicon or metal oxides, it is limited mostly to mechanically exfoliated samples or small-area thin-film-based single devices due to the limitation of growth technology.

### DISCLOSURE

### Technical Problem

The present disclosure is directed to providing a flexible thin-film transistor array which exhibits superior flexibility and device driving characteristics, and a method for preparing the same.

### Technical Solution

The present disclosure provides a flexible thin-film transistor using a two-dimensional semiconductor material, which includes: a flexible substrate; a channel formed on the flexible substrate and formed of a two-dimensional semiconductor material; a gate insulator and a gate electrode stacked sequentially on the channel; and source and drain electrodes formed on the channel as being spaced apart from the gate electrode.

In an exemplary embodiment of the present disclosure, the two-dimensional semiconductor material includes a transition metal dichalcogenide compound.

In an exemplary embodiment of the present disclosure, the two-dimensional semiconductor material including the transition metal dichalcogenide compound is formed on another substrate through chemical vapor deposition and then transferred to the flexible substrate.

In an exemplary embodiment of the present disclosure, the flexible substrate has a roughness of 1.5 nm or smaller.

The present disclosure also provides a flexible thin-film transistor array including at least two flexible thin-film transistors described above.

The present disclosure provides a method for preparing a flexible thin-film transistor, which includes: a step of sequentially forming a gate electrode and a gate insulator on a flexible substrate; a step of forming a channel by transferring a two-dimensional semiconductor material thin film formed on another substrate through chemical vapor deposition to the gate insulator; and a step of forming source and drain electrodes on the two-dimensional semiconductor material thin film.

In an exemplary embodiment of the present disclosure, the two-dimensional semiconductor material includes a transition metal dichalcogenide compound.

In an exemplary embodiment of the present disclosure, the two-dimensional semiconductor material includes any one selected from a group consisting of molybdenum disulfide (MoS₂), molybdenum diselenide (MoSe₂), molybdenum ditelluride (MoTe₂), tungsten disulfide (WS₂), tungsten diselenide (WSe₂) and tungsten ditelluride (WTe₂).

In an exemplary embodiment of the present disclosure, the flexible substrate has a roughness of 1.5 nm or smaller.

### Advantageous Effects

According to the present disclosure, a flexible thin-film transistor exhibiting superior flexibility and device driving characteristics at the same time can be prepared by transferring a two-dimensional semiconductor material with a thickness controlled to 50 nm or smaller onto a flatness-controlled flexible substrate through chemical vapor deposition. The flexible thin-film transistor can be utilized as a driving circuit of a display.

### BRIEF DESCRIPTION OF DRAWINGS

The patent or application file contains a least one drawing executed in color. Copies of this patent or patent application publication with color drawing(s) will be provided by the Office upon request and payment of the necessary fee.

FIG. 1 shows a photographic image of a thin-film transistor completed according to an exemplary embodiment of the present disclosure.

FIG. 2A to 2C show results of AFM analysis for validating the effectiveness of a flattening process.

FIG. 3A and 3B show results of analyzing single device operating characteristic data.

FIG. 4 shows a result of analyzing display pixel driving circuit characteristic data.

### BEST MODE FOR CARRYING OUT INVENTION

In the present disclosure, a flexible thin-film transistor is prepared by transferring a two-dimensional semiconductor material with a thickness controlled to 50 nm or smaller onto a flatness-controlled flexible substrate through chemical vapor deposition. In an exemplary embodiment of the present disclosure, the transition metal dichalcogenide compound molybdenum disulfide (MoS₂) may be used as the two-dimensional semiconductor material. Any one selected from a group consisting of molybdenum diselenide (MoSe₂), molybdenum ditelluride (MoTe₂), tungsten disulfide (WS₂), tungsten diselenide (WSe₂) and tungsten ditelluride (WTe₂) may also be used.

### EXAMPLE 1

Because it is difficult to use a commercially available polyimide film as a substrate for a flexible electronic device due to surface roughness, SU-8, which is an epoxy resin-based negative photoresist was coated and then treated with UV to reduce surface roughness.

Cr, Au and Pd layers were formed on the substrate through photolithography, thermal evaporation and lift-off processes for use as a gate of a thin-film transistor.

A gate insulator was formed on the gate layer by depositing an Al₂O₃ film through ALD (atomic layer deposition). Then, an active layer (channel) of a thin-film transistor was formed through wet transfer of a molybdenum disulfide thin film formed through chemical vapor deposition onto polystyrene as a supporting layer. After the transfer, the polystyrene supporting layer was dissolved using toluene.

Then, after forming an active layer pattern through photolithography, source and drain electrodes were formed thereon by depositing Ti and Au through photolithography, thermal evaporation and lift-off processes. Finally, a protective film was deposited by ALD to protect the thin-film transistor.

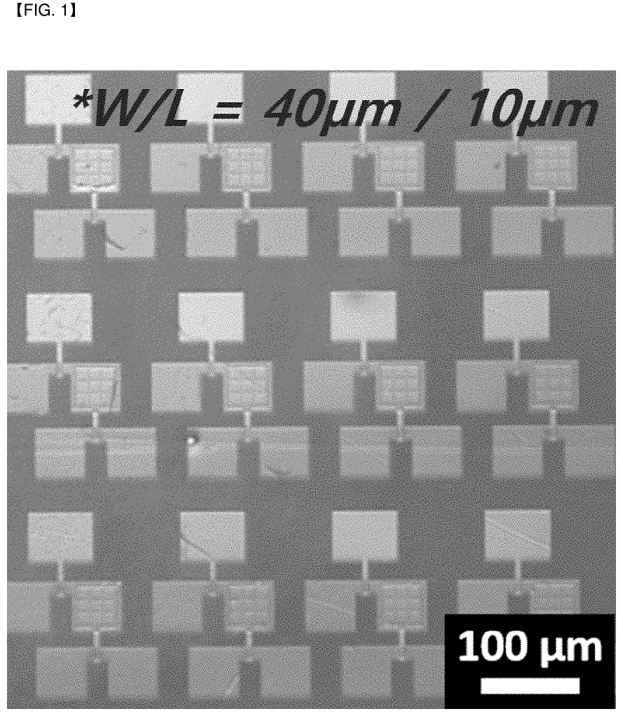

FIG. 1 shows a photographic image of the thin-film transistor completed according to an exemplary embodiment of the present disclosure.

### TEST EXAMPLE

First, AFM analysis was conducted to validate the effectiveness of the flattening process using the SU-8 epoxy resin-based negative photoresist.

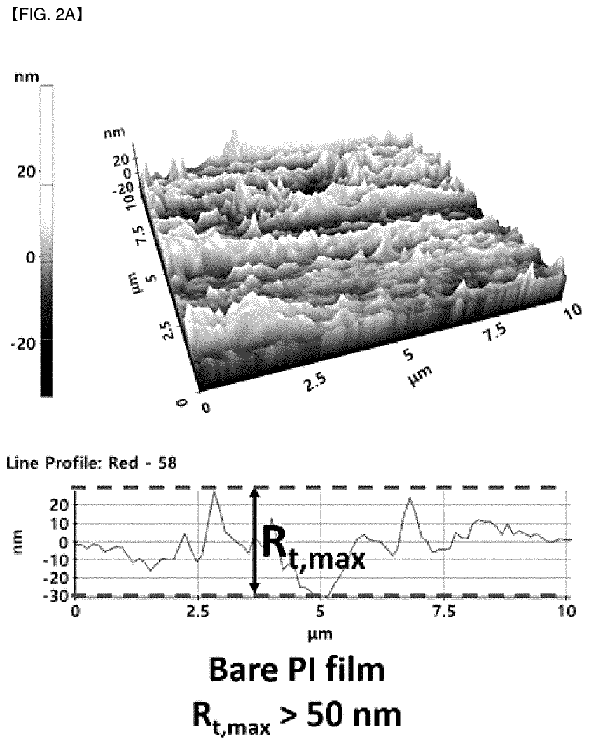

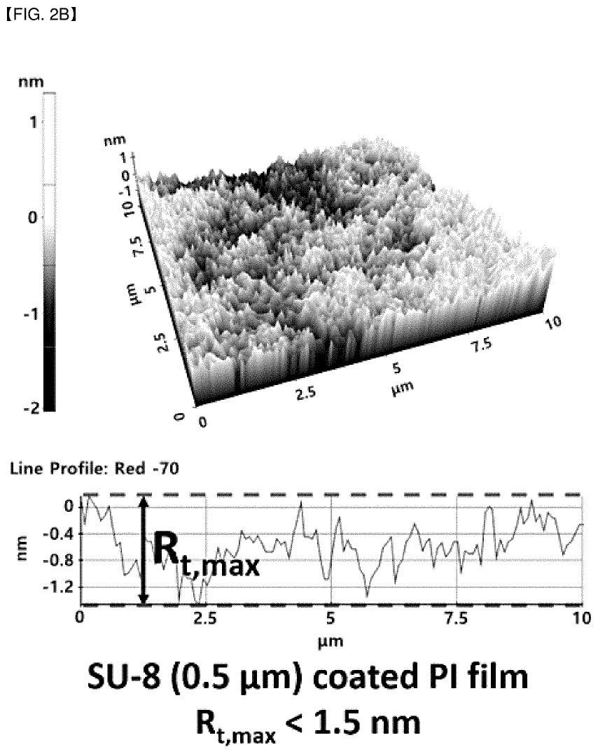

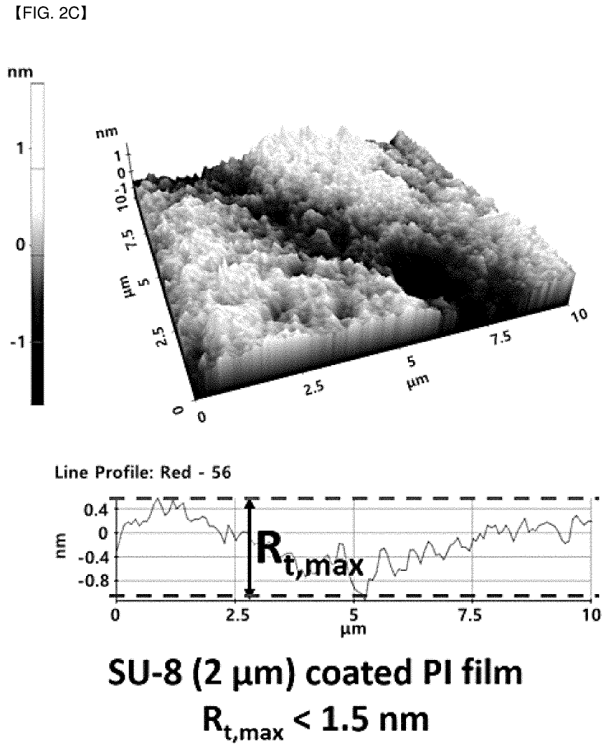

FIG. 2A to 2C show results of the AFM analysis for validating the effectiveness of the flattening process.

FIG. 2A to 2C show surface roughness: (2A) before the SU-8 coating; (2B) after coating to a thickness of 0.5 μm; and (2C) after coating to a thickness of 2 μm. Whereas (2A) shows a roughness of 50 nm or larger, (2B) and (2C) show a roughness of 1.5 nm or smaller. Considering that each layer of the thin-film transistor has a thickness of tens of nanometers, it can be seen that (2B) and (2C) will provide improved stability and yield during deposition or other processes.

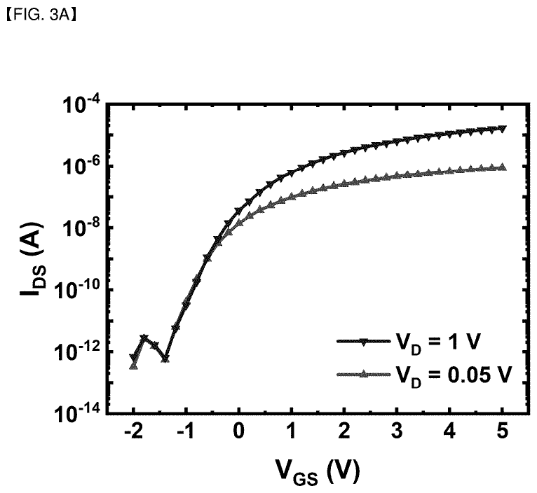

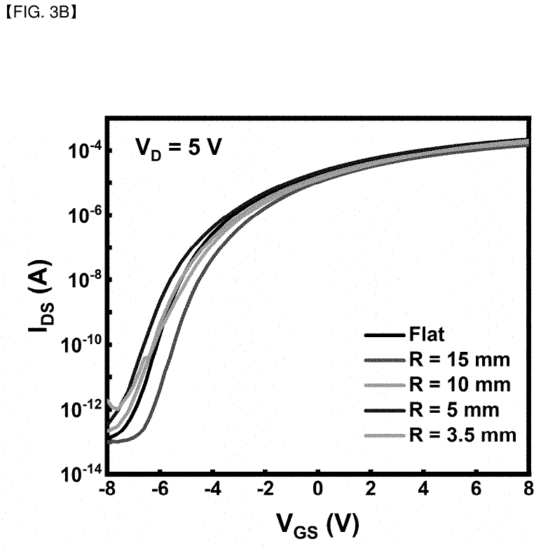

FIG. 3 show results of analyzing single device operating characteristic data.

Referring to FIG. 3A, it can be seen that, as a result of measuring the magnitude of source-drain current depending on gate voltage in order to check the basic operation of the thin-film transistor, the ON current is suitable for driving OLED pixels, etc. and the ON-OFF current ratio is suitable for control of pixel lightness.

FIG. 3B shows a result of conducting the same measurement while bending the substrate of the transistor. It can be seen that the operation of the transistor is maintained even at a curvature of about 3.5 mm.

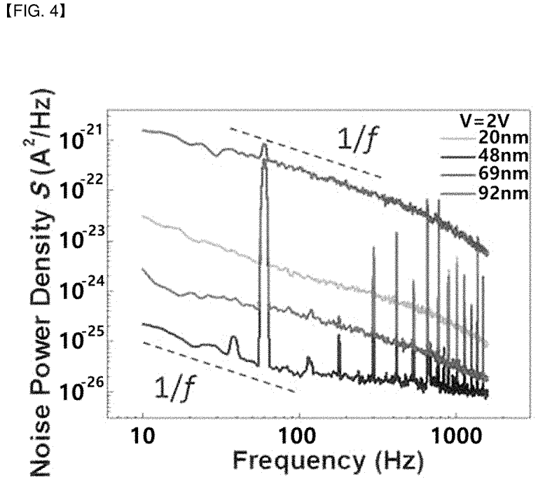

FIG. 4 shows a result of analyzing display pixel driving circuit characteristic data.

Referring to FIG. 4, the most basic OLED pixel driving circuit was realized using two transistors fabricated according to an exemplary embodiment of the present disclosure as one group, and its electrical properties were analyzed. FIG. 4 shows the result for (a) unbent state and (b) bent state with a curvature of 3.5 mm. It can be seen that the magnitude of current is controlled well depending on the applied voltage for both cases.

1. A flexible thin-film transistor using a two-dimensional semiconductor material, which comprises:
a flexible substrate;
a channel formed on the flexible substrate and formed of a two-dimensional semiconductor material;
a gate insulator and a gate electrode stacked sequentially on the channel; and
source and drain electrodes formed on the channel as being spaced apart from the gate electrode
wherein the flexible substrate has a roughness of 1.5 nm or smaller.

2. The flexible thin-film transistor according to claim 1, wherein the two-dimensional semiconductor material comprises a transition metal dichalcogenide compound.

3. The flexible thin-film transistor according to claim 2, wherein the two-dimensional semiconductor material comprising the transition metal dichalcogenide compound is formed on another substrate through chemical vapor deposition and then transferred to the flexible substrate.

4. A flexible thin-film transistor array comprising at least two flexible thin-film transistors according to claim 1.

5. A method for preparing a flexible thin-film transistor, which comprises:
a step of sequentially forming a gate electrode and a gate insulator on a flexible substrate;
a step of forming a channel by transferring a two-dimensional semiconductor material thin film formed on another substrate through chemical vapor deposition to the gate insulator; and
a step of forming source and drain electrodes on the two-dimensional semiconductor material thin film.

6. The method for preparing a flexible thin-film transistor according to claim 5, wherein the two-dimensional semiconductor material comprises a transition metal dichalcogenide compound.

7. The method for preparing a flexible thin-film transistor according to claim 6, wherein the two-dimensional semiconductor material comprises any one selected from a group consisting of molybdenum disulfide (MoS₂), molybdenum diselenide (MoSe₂), molybdenum ditelluride (MoTe₂), tungsten disulfide (WS₂), tungsten diselenide (WSe₂) and tungsten ditelluride (WTe₂).

8. The method for preparing a flexible thin-film transistor according to claim 5, wherein the flexible substrate has a roughness of 1.5 nm or smaller.
